(19) United States
(12) Patent Application Publication
(10) Pub. No.: US 2010/0147361 A1
(43) Pub. Date: Jun. 17, 2010

(54) Tandem junction photovoltaic device comprising copper indium gallium di-selenide bottom cell

(76) Inventor: Yung T. Chen, Davenport, FL (US)

Correspondence Address: MARLIN KNIGHT, P. O. BOX 1320, PIONEER, CA, 95666, US

(21) Appl. No.: 12/462,800

(22) Filed: Aug. 10, 2009

Related U.S. Application Data
(60) Provisional application No. 61/201,792, filed on Dec. 15, 2008.

(51) Int. Cl. H01L 31/05

(52) U.S. Cl. 136/249

(57) ABSTRACT

Embodiments of a monolithic tandem junction solar cell are described that include a CIGS bottom cell and top cell forming an n-i-p diode comprising n-type, i-type and p-type layers of a μc-SiCGe:H with approximate E_{g}=1.7 to 1.75 eV. Another embodiment of the top cell uses n-type, i-type and p-type μc-SiC:H. In another embodiment, the i-type layer comprises alternating layers of intrinsic μc-SiC:H and μc-SiGe:H. The thicknesses of these alternating layers are adjusted to achieve the desired effective composition of carbon and germanium and the desired optical band gap. Preferably this embodiment includes an n-type layer of μc-SiC:H and a p-type layer of μc-SiC:H. A superstrate embodiment is described that has a top cell forming a n-p diode with n-type and p-type polycrystalline SiCGe or SiC. In an alternative superstrate embodiment the p-type layer structure in top cell comprises alternating layers of pc-SiC and pc-SiGe.

### RELATED APPLICATIONS

The inventor of the present application filed a related application bearing Ser. No. 12/454,881 on May 26, 2009 titled “Multiple Junction Photovoltaic Devices and Process for Making the Same.” The Ser. No. 12/454,881 application is hereby incorporated herein by reference. Another related application by the present inventor is provisional application No. 61/201,792, filed Dec. 15, 2008, titled “STRUCTURES AND METHOD FOR FORMING HIGHLY STABLE PHOTOVOLTAIC FILMS”, which is also included by reference herein.

### BACKGROUND

1. Field of the Invention

The present invention relates to a monolithic integrated two terminal tandem junction structures for high efficiency photovoltaic devices (solar cells).

2. Description of the Prior Art

A lot of progress has been made in the past few decades for polycrystalline thin film photovoltaic devices comprised of II-VI and I-III-VI elemental group compounds. The record efficiencies of laboratory devices for single-junction solar cells are 16.5% for cadmium telluride (CdTe) and 19.9% for copper indium gallium di-selenide. Note that copper indium gallium di-selenide is typically referred to in the art by the acronym CIGS rather than the element symbols of CuInGaSe₂.

The most efficient prior art CIGS-based solar cells are grown on glass in a substrate configuration. A schematic is presented in FIG. 1. A layer of 0.4 to 0.6 μm of molybdenum (Mo) is deposited on soda lime glass for the back contact. The next layer is the p-type CIGS main absorber layer with thickness of 2.0 to 2.5 μm. Following the CIGS layer, thin cadmium sulfide (CdS) of 0.05 to 0.15 μm is deposited as the n-type part of the junction. A 0.05 to 0.12 μm of buffer layer consisting of a high-resistance i-ZnO is deposited in between CdS and AZO (aluminum zinc oxide, ZnO:Al). The 0.8 to 1.2 μm AZO functions as the front transparent conductive oxide (TCO) layer of the CIGS stack. An optional anti-reflection layer of MgF₂ of 0.08 to 0.13 μm thickness is deposited to improve the light trapping efficiency. Finally, Ni/Al grid is applied for external contact.

To further improve device efficiencies, one needs to look at multi-junction types of polycrystalline thin film solar cells. The efficiency benefit of a tandem solar cell to that of a single-junction cell has long been recognized, but it is practically realized only in expensive crystalline III-V materials or low-efficiency α-Si thin films. The optimum band gaps for two-terminal monolithic tandem (double) junction devices have been studied with a fixed set of device parameters using ideal models. The optimum band gaps were found to be 1.72±0.02 eV for the top cell and 1.14±0.02 eV for the bottom cell. The projected maximum efficiency is 30% as shown in FIG. 2. See Jef Poortmans, et al. “Thin Film Solar Cells . . . ”, page 160 (2006). As recognized by D. Young et al. from the National Renewable Energy Laboratory (NREL), these band gaps are ideally matched to the Cu—InSe₂ (0.95 eV)-CuGaSe₂ (1.7 eV) material system. (D. L. Young, et al., 2002, NREL/CP-520-31440.) Single-junction CuInₓGa₁₋ₓSe₂/CdS solar cells have achieved efficiencies of 19.9%, whereas CuGaSe₂/CdS cells have reached efficiencies greater than 9%. These cells, however, are quite sensitive to temperatures above 250° C., where diffusion destroys the p/n junction. This relatively low survival temperature for the individual cells has been identified as a fatal flaw for many thin-film tandem devices because of the need to grow good-quality absorber materials at temperatures above 500° C. by co-evaporation methods.

There have been several attempts to realize the theoretical efficiency prediction for tandem junction solar cell structure based on CIS or CIGS bottom absorber layer. Researchers from the University of South Florida led by C. Ferekides and D. Morel proposed a four-terminal tandem structure consisting of CIGS as the bottom cell and II-VI materials with band gap in the range 1.6-2.0 eV for the top cell. (See for example, P. Mahawela, et al. “II-VI compounds as the top absorbers in tandem solar cell structures,” Materials Science and Engineering B 116 (2005) 283-291.)

Their simulations indicate that the efficiency objectives can be met with either CdSe or Cadmium zinc telluride (CZT) as the top cell. They have attained internal J_{sc} of 18.3 mA/cm² and external J_{sc} of 14.3 mA/cm² for 1.7 eV CdSe absorbers. Single-phase Cd₁₋ₓZnₓTe (CZT; E_{g}=1.6-1.8 eV) films have been deposited by co-deposition on glass and flexible polyimide film substrates from the binary compounds using two deposition technologies. Their CZT absorber performance is limited by poor transport properties and influence from the contact layers. Due to the high processing temperature required (in the range of 500° C. to 600° C.) for bottom CIGS cell, their tandem structure can only be mechanically stacked to form four-terminal tandem cell structure, which has disadvantages of having complicated processing steps and reducing effective light absorption area.

X. Wu et al and researchers from NREL used their high performance CdTe cell as the top cell and CIS as the bottom cell to form a four-terminal tandem solar cell. (X. Wu, et al. “High-Efficiency CdTe Polycrystalline Thin-Film Solar Cells with an Ultra-Thin CuₓTe Transparent Back-Contact,” Materials Research Society Symp. Proc. Vol. 865, F11.4, 2005.) They developed an ultra-thin CuₓTe with a lower band gap of 1.08 eV, as a back contact for achieving high near infrared (NIR) transmission in the transparent CdTe top cell. As shown in FIG. 3, a modified borosilicate glass/CTO/ZTO/nano-CdS:O/CdTe/CuₓTe/ITO/Ni—Al grid device structure was used in their work for the top cell. A soda-lime glass/Mo/CIS/CdS/i-ZnO/c-ZTO/ITO/Ni—Al grid device structure was used for the bottom cell. They prepared a number of transparent single junction CdTe cells with total-area efficiencies of more than 13%. The highest-performance cell had a total-area efficiency of 13.94% (Voc=806.1 mV, Jsc=24.97 mA/cm², FF=69.22%, and area=0.41 cm²) with ˜60%-40% transmission in the wavelength range of 860-1300 nm. They also demonstrated a CdTe/CIS mechanically stacked tandem cell with total efficiency of 15.3% with 13.84% contribution from the top CdTe cell and 1.47% contribution from bottom CIS cell. The same limitation as above mentioned, due to the high processing temperature required for bottom CIS cell, the NREL tandem structure is limited to mechanically stacked to form four-terminal tandem cell structure, which is difficult to monolithically integrate.

Therefore there is a need for a high carrier collection top cell (E_{g}=1.7 eV to 1.75 eV) with low processing temperature to facilitate monolithic high efficiency tandem junction CIGS photovoltaic devices.

### SUMMARY

The present invention is made to overcome the above problems of the prior art and provide a novel high carrier collection, low processing temperature top cell to achieve high efficiency, monolithic tandem junction CIGS photovoltaic devices.

Therefore, according to one embodiment of the present invention, a novel substrate configuration, monolithic tandem junction solar cell made of a μc-SiCGe:H top cell and a CIGS bottom cell is provided for forming high efficiency photovoltaic devices. A first embodiment of a monolithic tandem junction solar cell structure according to the invention comprises:

a bottom cell, which has an approximate E_{g}=1.05 to 1.15 eV, including:
a p-type CIGS bottom absorber layer; and

a window layer of n-type cadmium sulfide (CdS); and

a top cell, which has an approximate E_{g}=1.7 to 1.75 eV, (forming an n-i-p diode from the direction of the incoming light.) including:
a p-type layer preferably of p-type μc-SiCGe:H; (μc=microcrystalline)
an intrinsic (i-type) layer preferably of i-type μc-SiCGe:H; and
an n-type layer preferably of n-type μc-SiCGe:H.
   In an alternative embodiment of the top cell, n-type μc-SiC:H can be used for the n-type layer, the i-type layer can be μc-SiC:H, and the p-type layer can be μc-SiC:H.

In another alternative embodiment, the i-type layer in the top cell comprises alternating layers (bi-layers) of intrinsic μc-SiC:H and μc-SiGe:H. The thickness of these alternating layers is adjusted to achieve the desired effective composition of carbon and germanium and the desired optical band gap. Preferably this embodiment includes an n-type layer of n-type μc-SiC:H and a p-type layer of p-type μc-SiC:H.

Another embodiment of the invention with a superstrate configuration is a monolithic tandem junction solar cell made of polycrystalline-SiCGe top cell and CIGS bottom cell. This embodiment comprises:

a top cell, forming a n-p diode from the direction of the incoming light, which has an approximate E_{g}=1.7 to 1.75 eV, including:
an n-type window layer preferably of n-type polycrystalline SiCGe (pc-SiCGe); and
a p-type absorber layer preferably of p-type (polycrystalline) pc-SiCGe; and

a bottom cell, which has an approximate E_{g}=1.05 to 1.15 eV, including:
an n-type cadmium sulfide (CdS) window layer; and
a p-type CIGS bottom absorber layer.
   In an alternative embodiment of the top cell described above the n-type window layer can is n-type pc-SiC and the p-type absorber layer is pc-SiC.

In another alternative embodiment the p-type layer structure in the n-p top cell comprises a plurality of pairs (bi-layers) of alternating layers of pc-SiC and pc-SiGe. (Note: pc stands for polycrystalline). The thicknesses of individual pc-SiC layers and pc-SiGe layers are adjusted to achieve a desired effective composition of carbon and germanium and hence the desired corresponding optical band gap of the p-type layer structure.

### BRIEF DESCRIPTION OF THE DRAWINGS

FIG. 1 is a schematic view showing the structure for a prior art single junction CIGS photovoltaic device.

FIG. 2 is a 2D plot showing the theoretical efficiency contour map of top cell E_{g} versus bottom cell E_{g} according to the prior art;

FIG. 3 is a schematic view of the prior art cell structure of a NREL proposed, mechanically stacked, four terminal tandem junction solar cell made of CdTe top cell and CIS bottom cell;

FIG. 4A is a schematic view showing the cell structure of one embodiment of the invention for a substrate configuration, monolithic tandem junction solar cell with an n-i-p diode top cell and CIGS bottom cell;

FIG. 4B is an illustration of the different absorption of red and yellow wavelength light in comparison to green and blue light in the solar cell embodiment of FIG. 4A;

FIG. 4C is an illustration of an embodiment of a top cell according to the invention with a plurality bi-layers forming the intrinsic (i-type) layer;

FIG. 5 is a schematic view showing a laser assisted PECVD apparatus for deposition of μc-SiCGe:H film according to the invention;

FIG. 6A is a schematic view showing the cell structure of an embodiment of the invention for a superstrate configuration, monolithic tandem junction solar cell with an n-p diode top cell and CIGS bottom cell;

FIG. 6B is a schematic view showing the top cell structure of an embodiment of the invention for use in the solar cell of FIG. 6A;

FIG. 7 is a schematic view showing the process flow according to an embodiment of the invention for making the cell structure for a substrate configuration, monolithic tandem junction solar cell with a μc-SiCGe:H top cell and CIGS bottom cell; and

FIG. 8 is a schematic view showing the process flow according to an embodiment of the invention for making the cell structure for a superstrate configuration, monolithic tandem junction solar cell with a polycrystalline-SiCGe top cell and CIGS bottom cell.

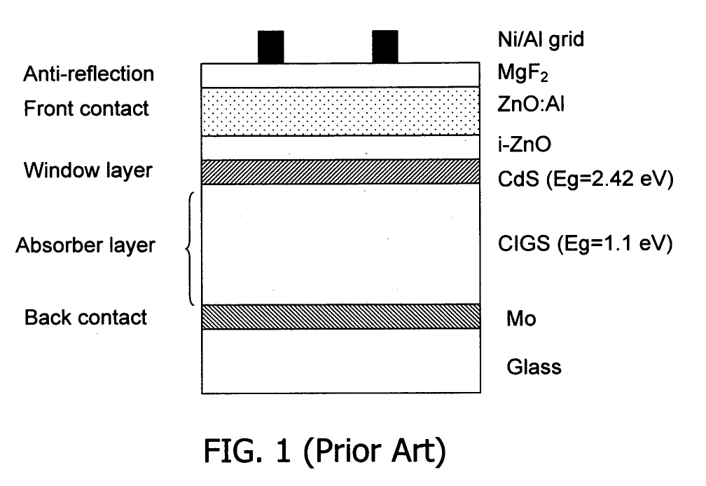

### DETAILED DESCRIPTION

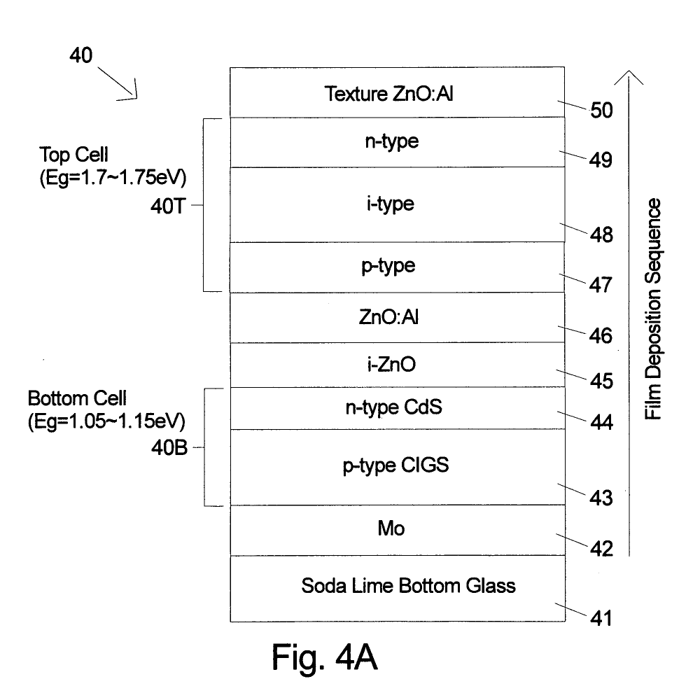

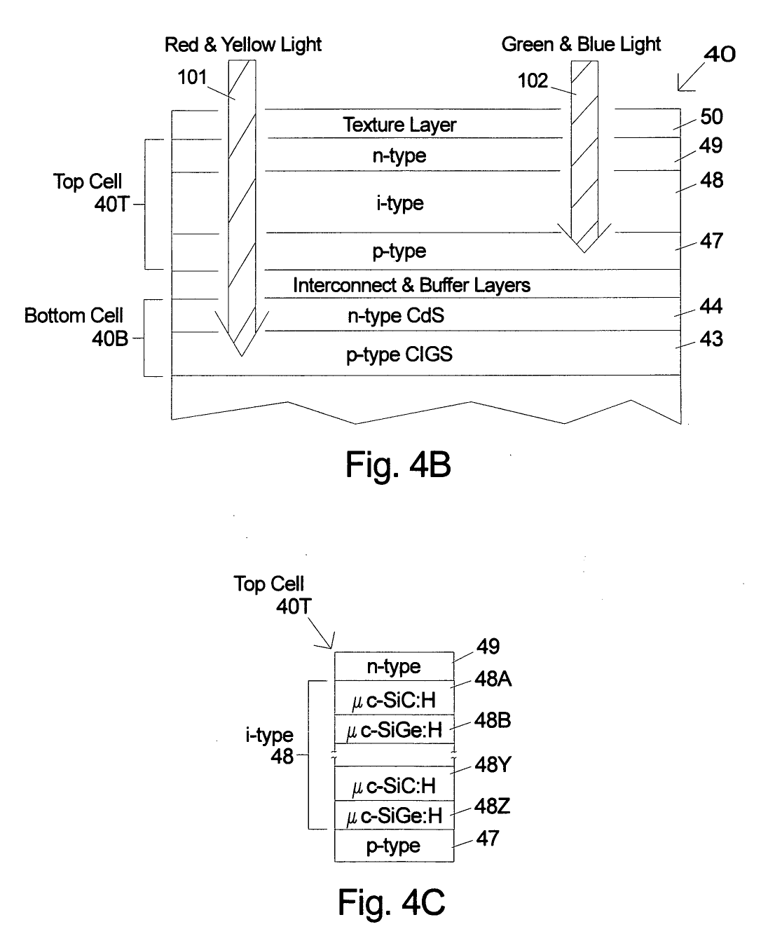

The first embodiment of the present invention will now be described with reference to FIG. 4A which shows a substrate configuration, monolithic tandem junction solar cell 40 with a top cell 40T, which has an approximate E_{g}=1.7 to 1.75 eV, and a CIGS bottom cell 40B, which has an approximate E_{g}=1.05 to 1.15 eV. (Note that none of the figures in this application are drawn according to scale because the large range of thicknesses as indicated herein would make the drawing unclear.) Top cell 40T forms a n-i-p diode from the direction of incoming light, which is from the top of the page as shown, as well as a p-i-n diode from the direction of bottom cell. The bottom cell layers form a heterogeneous rectifying n-p junction. The top cell 40T in one embodiment includes a p-type layer 47 of p-type hydrogenated microcrystalline silicon carbon germanium (μc-SiCGe:H), a i-type layer 48 of intrinsic (i-type) μc-SiCGe:H, and an n-type layer 49 of n-type μc-SiCGe:H. The bottom cell 40B includes a p-type CIGS bottom absorber layer 43, and a thin cadmium sulfide (CdS) window layer 44 deposited as the n-type part of the bottom cell heterogeneous rectifying junction.

Referring to FIG. 4A, the illustrated embodiment of solar cell structure 40 comprises a soda lime bottom glass 41 followed by a layer of 0.4 to 0.6 μm of molybdenum (Mo) 42 for the back contact deposited on the soda lime glass. Note that in FIG. 4A the layers are deposited in order starting at the bottom of the page as shown. The bottom cell 40B follows the Mo layer 42 and consists of a p-type CIGS bottom absorber layer 43 with thickness of 2.0 to 2.5 μm followed by a thin cadmium sulfide (CdS) window layer 44 of 0.05 to 0.15 μm deposited as the n-type part of the bottom cell junction.

The bottom cell 40B is followed by a buffer layer 45 of a high electrical resistance i-ZnO 0.05 to 0.12 μm thick deposited on the CdS window layer 44. An interconnect tunneling TCO layer 46 is next which consists of AZO (aluminum zinc oxide, ZnO:Al) 0.3 to 0.5 μm thick, deposited on the buffer layer 45.

The top cell 40T (also called the top absorber cell) follows the TCO layer 46. The top cell 40T in this embodiment includes a p-type layer 47 of p-type μc-SiCGe:H about 0.01 to 0.03 μm thick. The i-type layer 48 of intrinsic (i-type) μc-SiCGe:H is about 2.0 to 2.5 μm thick. The n-type layer 49 is n-type μc-SiCGe:H about 0.01 to 0.03 μm thick.

A textured front TCO layer 50 of 0.5 to 0.8 μm of ZnO:Al is formed on the upper layer 49 of the top cell 40T. Optionally an EVA/transparent top glass can be laminated on the whole structure for encapsulation and packaging.

The tandem junction μc-SiCGe:H/CIGS solar cell embodiment according to the invention with two band gap energies will increase the absorption bandwidth of the incoming light. The top cell with band gap energy of 1.7 eV˜1.75 eV will convert the photons with energy greater than 1.7 eV˜1.75 eV, which is in the range of blue and green light. In FIG. 4B the arrows 101, 102 illustrate different wavelength bands of light which will be referred to generally as colored light corresponding to different wavelength bands. Arrow 101 illustrates red and yellow bands of light, which have longer wavelength and smaller band gap energy). These lower energy bands of light will not be absorbed by top cell 40T because it has higher band gap energy. Thus, photons of red and yellow light pass through the layers of the top cell 40T and are absorbed by bottom cell 40B, specifically by the p-type CIGS layer 43 in this embodiment. Arrow 102 illustrates green and blue bands of light, which have shorter wavelength and higher band gap energy). These higher energy bands of light will be absorbed by top cell 40T, specifically by the p-type μc-SiCGe:H layer 47 in this embodiment.

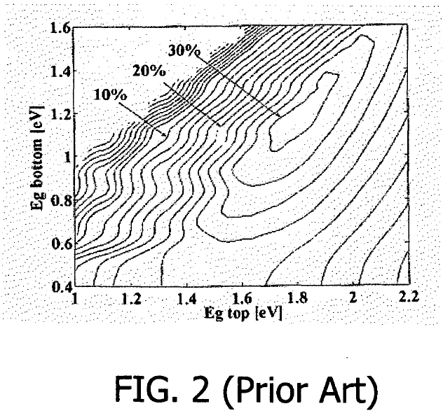

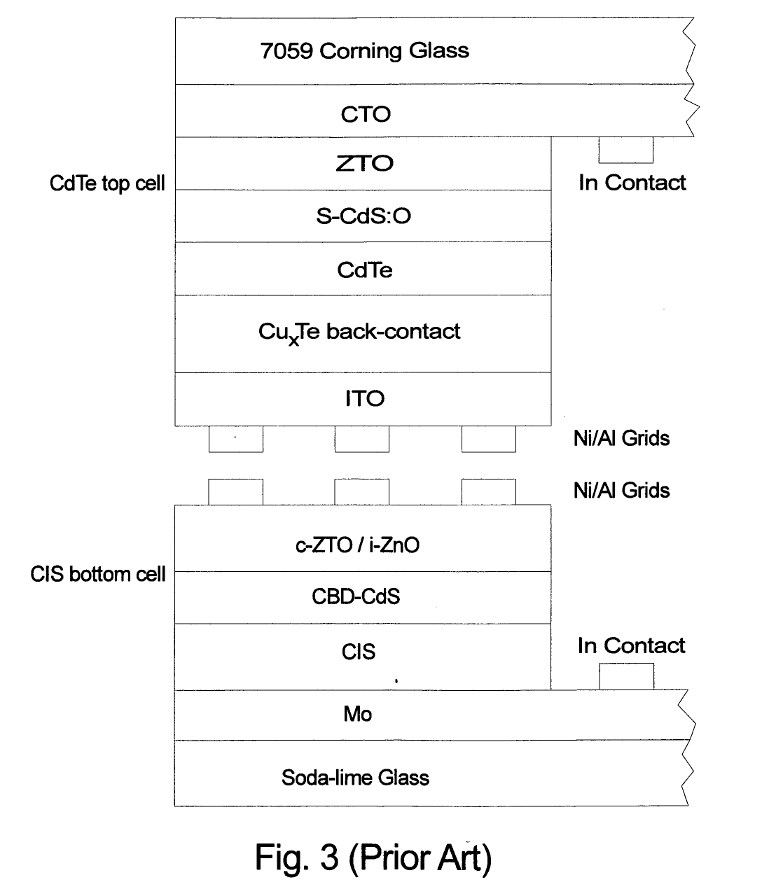

The bottom CIGS cell with band gap energy of 1.05 eV˜1.15 eV will convert the photons with energy greater than 1.05 eV˜1.15 eV, in the range of red and yellow light. With tandem junctions of 1.72 eV and 1.1 eV, the absorption spectrum can cover the full range of visible and infrared light from 400 nm to 1000 nm thus increasing the efficiency of the tandem cell. The theoretical efficiency of top cell E_{g} of 1.72 eV and bottom E_{g} of 1.1 eV can achieve 30% as indicated in FIG. 2.

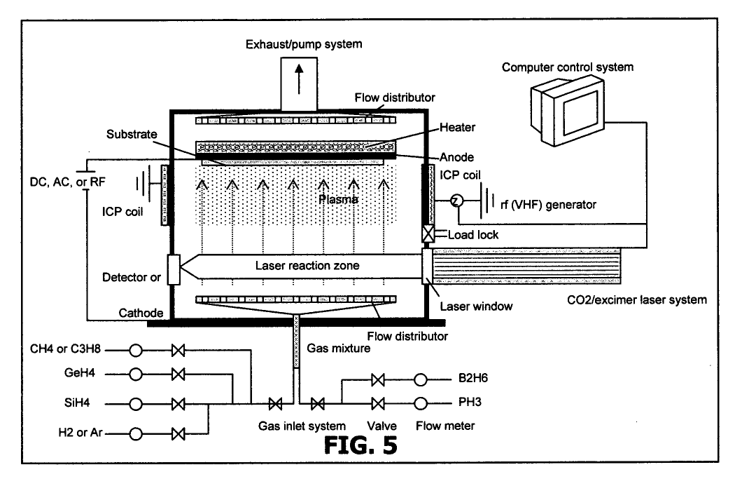

The p-type layer 47 of μc-SiCGe:H can be deposited by PECVD of thickness in the range of 0.01 to 0.03 μm using B₂H₆ or BCl₃ doping gas. The un-doped intrinsic μc-SiCGe:H for i-type layer 48 has a thickness in this embodiment in the range of 2.0 to 2.5 μm. The n-type layer 49 of μc-SiCGe:H has a thickness is in the range of 0.01 to 0.03 μm and can be deposited by PECVD using PH₃ doping gas. The μc-SiCGe:H can be normally deposited by various forms of PECVD with a low processing temperature in the range of 150° C. to 250° C., which is critical not to destroy the junction of the bottom CIGS cell. FIG. 5 is a schematic view showing a laser assisted PECVD apparatus to deposit μc-SiCGe:H top cell. RF magnetron sputtering or DC pulsed magnetron sputtering can also be used to deposit μc-SiCGe:H as well with commercially available targets.

The hydrogenation of the materials in the thin films described herein can be achieved during the deposition process by prior art methods. For example, hydrogenated amorphous silicon (a-Si:H) is achieved by mixing H₂ and SiH₄ during PECVD (Plasma Enhanced Chemical Vapor Deposition). The ratio between H₂ and SiH₄, called hydrogen dilution ratio R, is defined as [H₂]/[SiH₄]. Depending on the nature of the underlayer substrate, hydrogen dilution ratio R has strong effect on the crystallinity of the silicon film. For example, on crystalline silicon substrate with a deposition temperature of 200 C, if the R value is greater than 15˜20, the deposited film will be microcrystalline form (μc-Si:H). For R less than 10, the deposited film will be amorphous (a-Si:H). The threshold R between amorphous and microcrystalline transition depends strongly on the substrate, processing temperature, pressure, and RF power etc. The actual atomic percentage (at. %) of hydrogen in the film that results from this process is difficult to determine and varies widely, for example between 3 at. % to 25 at. %. For this reason, the at. % of hydrogen in thin films for solar cells is generally not quoted in the literature. Therefore, all of the atomic percentages given in this specification are exclusive of the amount of hydrogen in the respective films.

For the case of μc-SiCGe:H, the hydrogen dilution ratio R is defined as [H₂]/([SiH₄]+[CH₄]+[GeH₄]). The preferred R value is about 20 to 80. For the μc-SiC:H, the hydrogen dilution ratio is defined as [H₂]/([SiH₄]+[CH₄]). The preferred R value is in the range of 20 to 50.

Gases from a plurality of external gas sources for forming semiconductor films, such as monosilane (SiH₄), germane (GeH₄), methane (CH₄), propane (C₃H₈), hydrogen (H₂), diborane (B₂H₆), and phosphine (PH₃), are controlled by a set of corresponding mass flow controllers (MFCs) and control valves and pass through multiple gas delivery lines (examples of which are shown) to a gas mixer. The resulting film forming gas in the mixer passes through an inlet valve and is introduced into the chamber via a gas inlet port which extends through the top wall of the vessel dome. The post-reaction gas in the chamber is removed by a pumping system through an output port, which is connected to a throttling valve for controlling the chamber pressure.

As would be understood by a person of skill in the art, the actual film forming gas used and the actual connection of delivery lines to the gas mixer may vary depending on the desired film forming reaction in the chamber. For example, a silicon-containing gas, such as monosilane (SiH₄), disilane (Si₂H₆), trisilane (Si₃H₈), silicon tetrafluoride (SiF₄), silicon tetrachloride (SiCl₄), monomethylsilane (SiH₃CH₃), hexamethyldisilane (Si₂(CH₃)₆), dichlorosilane (H₂SiCl₂) or trichlorosilane (HSiCl₃), may be used to form hydrogenated amorphous silicon (a-Si:H), hydrogenated nanocrystalline silicon (nc-Si:H), or polycrystalline Si film. In addition to the above Si-contained gas, hydrogen (H₂) gas may be added thereto for suppressing defect formation in the Si film. A semiconductor film containing Si and carbon (C) may be formed by using a mixture of the above Si-contained gas and a C-contained gas, such as methane (CH₄), acetylene (C₂H₂), ethylene (C₂H₄), ethane (C₂H₆), propylene (C₃H₆) or propane (C₃H₈). A semiconductor film containing Si and germanium (Ge) may be produced by using a mixture of the above Si-containing gases and a Ge-containing gas, such as germane (GeH₄), monomethylgermane (GeH₃CH₃) or dimethylgermane (GeH₂(CH₃)₂). A semiconductor film containing Si, Ge and C may be formed by using a mixture of the above Si-containing gases, the above Ge-containing gases and the above C-containing gases. For forming a p-type or n-type semiconductor film, an additional dopant gas, such as diborane (B₂H₂), trimethylborane (B(CH₃)₃), phosphine (PH₃) or phosphorus trichloride (PCl₃), is introduced into the mixer via a delivery line separate from delivery lines for above-mentioned Si, Ge and C-containing film-forming gases.

The micro-crystalline μc-SiCGe:H is a very stable structure against light induced degradation which is the main degradation mechanism for a-Si:H solar cell. In an alternative embodiment, of the top cell 40T of FIG. 4A has a p-type layer 47 of p-type μc-SiC:H, and the i-type (intrinsic) layer 48 is un-doped μc-Si_{1-x-y}CₓGe_{y}:H with an optical band gap of 1.7-1.75 eV, where x is 35-40 at. % and y is 10-30 at. %. As noted above the hydrogen content is typically not specified, so all of the atomic percentages given in this specification are exclusive of the amount of hydrogen in the film. This alternative embodiment has n-type μc-SiC:H for the n-type layer 49.

In another embodiment, the top cell 40T includes a p-type layer 47 of μc-SiC:H; an un-doped μc-Si₁₋ₓCₓ:H intrinsic layer 48 having an optical band gap of 1.7-1.75 eV, where x is 30-45 at. %; and an n-type layer of hydrogenated nanocrystalline silicon carbon (nc-SiC:H).

In still another embodiment, the top cell 40T as illustrated in FIG. 4C includes a intrinsic i-type layer 48 comprising a plurality of alternating layers (bi-layers) of μc-SiC:H 48A, 48Y and μc-SiGe:H 48B, 48Z. Only two bi-layer pairs are shown, but the preferred structure can have from 40 to 80 bi-layers of μc-SiC:H/μc-SiGe:H, which are deposited to achieve the preferred overall thickness of the intrinsic layer in the range of 1 to 6 μm with the thicknesses of individual μc-SiC:H layers and μc-SiGe:H layers being 20-30 nm and 10-20 nm, respectively. The intrinsic layer in this embodiment comprises alternating layers of un-doped μc-SiC:H and μc-SiGe:H, which have an effective optical band gap of 1.7-1.75 eV. The effective composition and hence the corresponding optical band gap of the intrinsic layer of the top cell may be controlled by adjusting the thicknesses of individual μc-SiC:H layer and μc-SiGe:H layer such that effective compositions of 35-45 at. % carbon, 10-30 at. % germanium and the remaining balance silicon are attained. In this embodiment preferably the n-type layer 49 is μc-SiC:H and the p-type layer 47 is μc-SiC:H. The thickness of the p-type μc-SiC:H layer and n-type μc-SiC:H layer is about 10-20 nm. The details of the above mentioned descriptions can be referenced to the related application bearing Ser. No. 12/454,881 on May 26, 2009 titled “Multiple Junction Photovoltaic Devices and Process for Making the Same.”, included by reference herein.

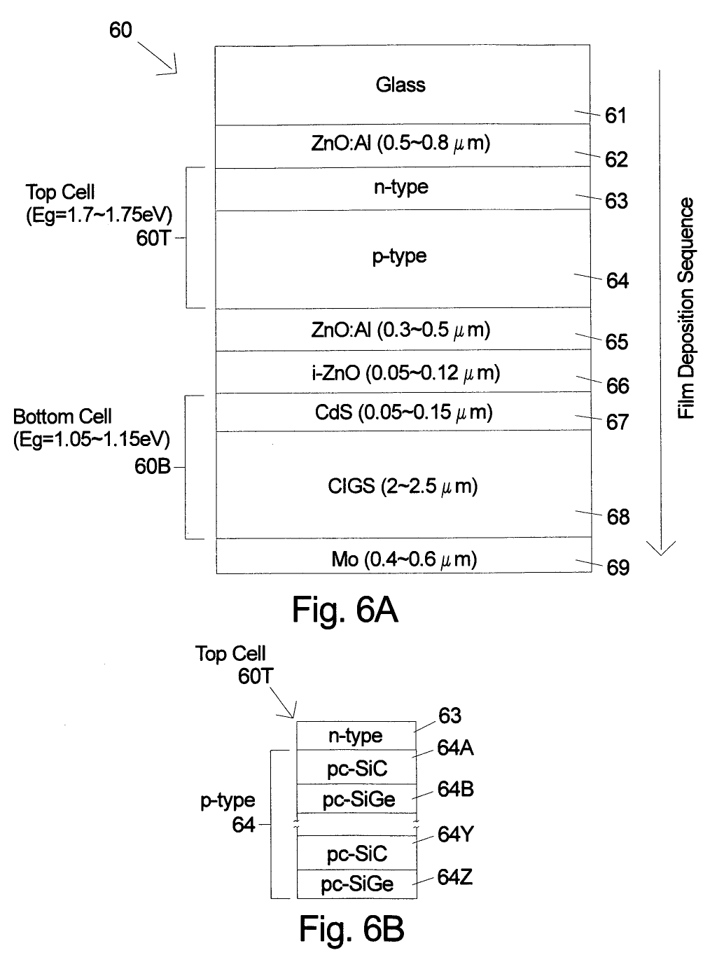

Another embodiment of the present invention as applied to a superstrate configuration, monolithic tandem junction solar cell made of polycrystalline-SiCGe top cell and CIGS bottom cell for forming high efficiency solar cell structures will now be described with reference to FIG. 6A. Note that in FIG. 6A the layers are deposited in order starting at the top of the page as shown and the incoming light enters from the top of the page. Referring now to FIG. 6A, the illustrated solar cell structure 60 comprises a top soda lime glass layer 61 which is followed by a transparent conducting oxide (TCO) layer 62, preferably made of alumina-doped zinc oxide (ZnO:Al) as shown or alternatively fluorinated tin oxide (SnO:F) can be used. A top cell 60T is of the n-p diode type (from the direction of the incoming light) and consists of a n-type window layer 63, which is deposited on layer 62, followed by a p-type absorber layer 64. The n-type window layer 63 in this embodiment is 0.03 to 0.12 μm of n-type polycrystalline silicon carbon germanium SiCGe (pc-SiCGe). The p-type absorber layer 64 is p-type pc-SiCGe having thickness of 3 to 5 μm. The top cell 60T is followed by interconnect tunneling TCO layer 65 which is 0.3 to 0.5 μm of ZnO:Al. A high electrical resistance buffer layer 66 of i-ZnO 0.05 to 0.12 μm thick is formed on the interconnect tunneling TCO layer 65. A bottom cell 60B is next consisting of n-type bottom window layer 67 followed by a p-type CIGS bottom absorber layer 68. The bottom window layer 67 is thin n-type cadmium sulfide (CdS) about 0.05 to 0.15 μm thick. The p-type CIGS bottom absorber layer 68 has a thickness of about 2.0 to 2.5 μm. A layer of 0.4 to 0.6 μm of molybdenum (Mo) follows as the back contact 69. Optionally an EVA/transparent bottom glass can be laminated to the whole structure for encapsulation and packaging.

The solar cell 60 is designed for light to enter from the top of the page as the structure in oriented in FIG. 6A. Similar to what was described for solar cell 40, in the embodiment 60 of FIG. 6A, in the completed cell, photons of red and yellow light pass through the layers of the top cell 60T (as well as layers 61, 62, 65, 66 and bottom window layer 67) and are then absorbed by the p-type CIGS bottom absorber layer 68. Green and blue bands of light, which have shorter wavelength and higher band gap energy, will be absorbed by top cell 60T, specifically by the p-type absorber layer 64 after passing through layers 61, 62. 63.

In another embodiment, the top cell 60T of FIG. 6A the n-type layer 63 is an n-type polycrystalline-SiC, and the p-type layer 64 is a p-type polycrystalline Si_{1-x-y}CₓGe_{y} layer with an optical band gap of 1.7-1.75 eV, where x is 35-40 at. % and y is 10-30 at. %. In another embodiment the top cell 60T has an n-type polycrystalline SiC layer 63 and a p-type polycrystalline Si₁₋ₓCₓ layer having an optical band gap of 1.7-1.75 eV, where x is 30-45 at. %.

Another embodiment of the top cell 60T is illustrated in FIG. 6B. In this embodiment the n-type layer 63 is polycrystalline-SiC and the p-type layer 64 comprises a plurality of pairs (bi-layers) of alternating layers of pc-SiC 64A, 64Y and pc-SiGe 64B, 64Z. (Note: pc stands for polycrystalline). The thickness of the n-type pc-SiC layer in this embodiment is about 10-20 nm. The p-type polycrystalline layer 64 in this embodiment has an effective optical band gap of 1.7-1.75 eV. The thicknesses of individual pc-SiC layers and pc-SiGe layers are 20-30 nm and 10-20 nm, respectively in this embodiment. The effective composition and hence the corresponding optical band gap of the p-type polycrystalline layer of the top cell may be controlled by adjusting the thicknesses of individual pc-SiC layers and pc-SiGe layers such that effective compositions of 35-45 at. % carbon, 10-30 at. % germanium and the remaining balance silicon are attained. The preferred overall thickness of the p-type polycrystalline layer is in the range of 3 to 5 μm, which can be attained by laminating 40 to 80 bi-layers of pc-SiC/pc-SiGe.

The polycrystalline SiCGe can be deposited by LPCVD or PECVD with a moderate processing temperature in the range of 350° C. to 500° C. Because the top polycrystalline SiCGe layers are deposited before bottom CIGS cell and their junction is less sensitive to subsequent high processing temperature during CIGS deposition, the tandem pc-SiCGe/CIGS cell can be made to achieve high efficiency without degradation of the CIGS layer due to temperature sensitivity. The CIGS can be deposited by RF magnetron sputtering or DC pulsed magnetron sputtering at a relatively low temperature. RF magnetron sputtering or DC pulsed magnetron sputtering can be used to deposit pc-SiCGe as well with available targets. This will make it possible for building the full tandem pc-SiCGe/CIGS stack by in-line sputtering process.

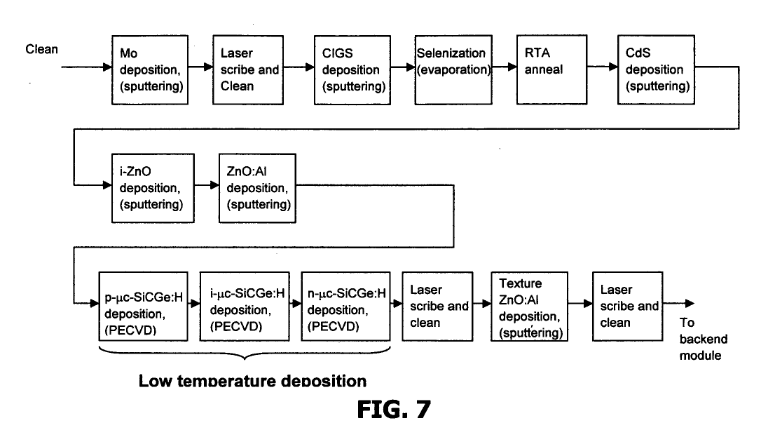

FIG. 7 is a schematic view showing one embodiment of an in-line process for making a high efficiency substrate configuration, monolithic tandem junction solar cell with a μc-SiCGe:H top cell and CIGS bottom cell according to the invention. The process includes pre-cleaning the soda lime glass and depositing 0.4 to 0.6 μm of molybdenum (Mo) as the back contact on top of soda lime glass by RF or DC pulsed magnetron sputtering in the temperature range of 150° C. to 250° C. A first laser scribing and cleaning process on the Mo layer then define the back contact circuit. Next the CIGS bottom absorber layer is deposited as a p-type 2.0 to 2.5 μm thick by RF or DC pulsed magnetron sputtering in the temperature range of 200° C. to 450° C.; followed by an optional selenization process by solid Se vapor evaporation deposition in conjunction with a rapid thermal anneal (RTA) in the temperature range of 500° C. to 560° C. A thin cadmium sulfide (CdS) window layer of 0.05 to 0.15 μm is deposited by RF or DC pulsed magnetron sputtering in the temperature range of 250° C. to 450° C. as the n-type part of the bottom junction. Then a buffer layer of 0.05 to 0.12 μm of i-ZnO is deposited by RF or DC pulsed magnetron sputtering in the temperature range of 200° C. to 450° C. Next the interconnect tunneling TCO layer is formed by depositing a 0.3 to 0.5 μm of ZnO:Al (AZO) by RF or DC pulsed magnetron sputtering in the temperature range of 200° C. to 450° C. Fabrication of the top cell begins by depositing a 0.01 to 0.03 μm of p-type μc-SiCGe:H top cell sub-layer by PECVD with the chamber temperature in the range of 150° C. to 250° C.; followed by depositing a 2 to 2.5 μm of un-doped intrinsic μc-SiCGe:H top absorber layer by PECVD with the chamber temperature in the range of 250° C. to 250° C. The top cell is completed by depositing a 0.01 to 0.03 μm of n-type μc-SiCGe:H top cell sub-layer by PECVD with the chamber temperature in the range of 150° C. to 250° C. Next a second laser scribing and cleaning process defines the conduction path for absorbers. A textured front TCO of 0.5 to 0.8 μm of ZnO:Al is then formed by RF or DC pulsed magnetron sputtering in the temperature range of 200° C. to 450° C. Third laser scribing and cleaning process then defines the front contact circuit; and is followed by back end process for cell encapsulation and module package. Optionally an EVA/transparent top glass can be laminated to the whole structure for encapsulation and packaging for the backend process.

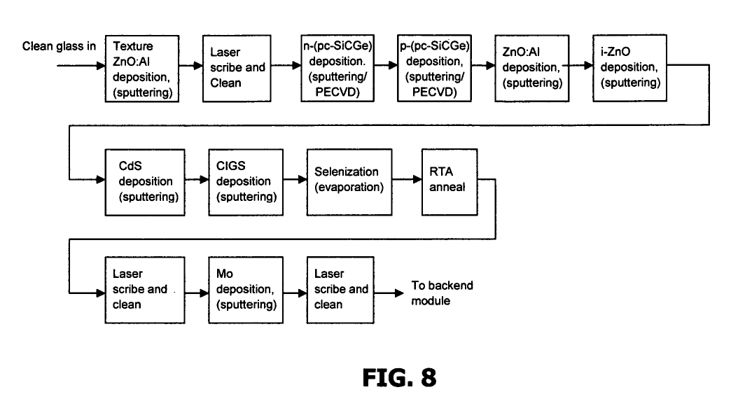

FIG. 8 is a schematic view showing another embodiment of an in-line process for making a high efficiency superstrate configuration, monolithic tandem junction solar cell made of polycrystalline SiCGe top cell and CIGS bottom cell according to the invention. The process includes pre-cleaning the soda lime glass and then depositing a transparent conducting oxide (TCO) of 0.5 to 0.8 μm by RF or DC pulsed magnetron sputtering in the temperature range of 200° C. to 450° C., preferably made of fluorinated tin oxide (SnO:F) or alumina doped zinc oxide (ZnO:Al). A top cell is then formed which consists of 0.03 to 0.12 μm of n-type polycrystalline SiCGe (pc-SiCGe) window layer and 3 to 5 μm p-type polycrystalline SiCGe absorber layer by PECVD in the temperature range of 350° C. to 500° C. The next step deposits a 0.3 to 0.5 μm of ZnO:Al interconnect tunneling layer between the top and bottom cell by RF or DC pulsed magnetron sputtering in the temperature range of 200° C. to 450° C. A buffer layer is then deposited of 0.05 to 0.12 μm of i-ZnO by RF or DC pulsed magnetron sputtering in the temperature range of 200° C. to 450° C. Next is the fabrication of a bottom cell consisting of 0.05 to 0.15 μm n-type cadmium sulfide (CdS) window layer and 2.0 to 2.5 μm p-type CIGS bottom absorber layer by RF or DC pulsed magnetron sputtering in the temperature range of 200° C. to 450° C.; followed by an optional selenization process by solid Se vapor evaporation deposition in conjunction with a rapid thermal anneal (RTA) in the temperature range of 500° C. to 560° C. Then a second laser scribing and cleaning process defines the conduction path for absorbers. Next a layer of 0.4 to 0.6 μm of molybdenum (Mo) is deposited as the back contact by RF or DC pulsed magnetron sputtering in the temperature range of 150° C. to 250° C. A third laser scribing and cleaning process defines the back contact circuit. Optionally an EVA/transparent bottom glass can be laminated to the whole structure for encapsulation and packaging for the backend process.

What is claimed is:

1. A tandem junction photovoltaic device comprising:
a top cell including a first n-type layer, an i-type layer disposed in contiguous contact with the n-type layer, and a first p-type layer disposed in contiguous contact with the i-type layer, the first n-type layer, i-type layer and first p-type layer forming an n-i-p diode and having a band gap energy of approximately 1.7 to 1.75 eV; and
a bottom cell comprising a second n-type layer of n-type cadmium sulfide and a second p-type layer of copper indium gallium di-selenide disposed in contiguous contact with the second n-type layer, the bottom cell having a second band gap energy approximately from 1.05 to 1.15 eV.

2. The tandem junction photovoltaic device of claim 1 wherein the first n-type layer is n-type hydrogenated microcrystalline silicon carbon germanium (μc-SiCGe:H), the i-type layer is i-type hydrogenated microcrystalline silicon carbon germanium (μc-SiCGe:H), and the first p-type layer is p-type hydrogenated microcrystalline silicon carbon germanium (μc-SiCGe:H).

3. The tandem junction photovoltaic device of claim 1 wherein the first n-type layer is hydrogenated microcrystalline silicon carbon (μc-SiC:H), the first p-type layer is p-type hydrogenated microcrystalline silicon carbon (μc-SiC:H) and the i-type layer is i-type hydrogenated microcrystalline silicon carbon germanium (μc-S_{1-x-x-y}CₓGe_{y}:H) where x is 35-40 at. % and y is 10-30 at. % exclusive of hydrogen content.

4. The tandem junction photovoltaic device of claim 1 wherein the first p-type layer is p-type hydrogenated microcrystalline silicon carbon (μc-SiC:H), the i-type layer is i-type hydrogenated microcrystalline silicon carbon (μc-Si₁₋ₓCₓ:H), where x is 30-45 at. % exclusive of hydrogen content; and the first n-type layer is hydrogenated nanocrystalline silicon carbon (nc-SiC:H).

5. The tandem junction photovoltaic device of claim 1 wherein the i-type layer comprises a plurality of alternating layers of μc-SiC:H and μc-SiGe:H.

6. The tandem junction photovoltaic device of claim 5 wherein the i-type layer comprises at least 40 alternating layers of μc-SiC:H and μc-SiGe:H.

7. The tandem junction photovoltaic device of claim 5 wherein the i-type layer has an effective composition of 35-45 at. % carbon and 10-30 at. % germanium exclusive of hydrogen content.

8. The tandem junction photovoltaic device of claim 5 wherein the first n-type layer is n-type μc-SiC:H and the first p-type layer is μc-SiC:H.

9. The tandem junction photovoltaic device of claim 1 further comprising a textured TCO layer of ZnO:Al disposed above the top cell.

10. The tandem junction photovoltaic device of claim 1 further comprising a middle interconnect TCO layer disposed in contiguous contact with the first p-type layer of the top cell; and an intrinsic zinc oxide barrier layer disposed in contiguous contact with the middle interconnect TCO layer.

11. A tandem junction photovoltaic device comprising:
a top cell having a first band gap energy of approximately 1.7-1.75 eV and comprising an n-type layer of a polycrystalline alloy of silicon carbon, and a p-type layer of a polycrystalline alloy of silicon carbon disposed in contiguous contact with the n-type layer, thereby forming a rectifying junction; and
a bottom cell having a second band gap energy lower than the first band gap energy, and including an n-type cadmium sulfide layer and a p-type copper indium gallium di-selenide layer disposed in contiguous contact with the n-type cadmium sulfide layer, thereby forming a heterogeneous rectifying junction.

12. The tandem junction photovoltaic device of claim 11 wherein the p-type layer is polycrystalline silicon carbon germanium (Si₍₁₋ₓ₎CₓGe_{y}), where x is 35-40 at. % and y is 10-30 at. %.

13 The tandem junction photovoltaic device of claim 11 wherein the p-type layer is polycrystalline silicon carbon with carbon content of approximately 30-45 at. %.

14. A tandem junction photovoltaic device comprising:
a top cell having a first band gap energy of approximately 1.7-1.75 eV and comprising an n-type layer of a polycrystalline alloy of silicon carbon, and a p-type layer structure disposed in contiguous contact with the n-type layer, thereby forming a rectifying junction, the p-type layer structure comprising a plurality of alternating layers of p-type polycrystalline silicon carbon (pc-SiC) and p-type polycrystalline silicon germanium (pc-SiGe); and
a bottom cell having a second band gap energy lower than the first band gap energy, and including an n-type cadmium sulfide layer and a p-type copper indium gallium di-selenide layer disposed in contiguous contact with the n-type cadmium sulfide layer, thereby forming a heterogeneous rectifying junction.

15. The tandem junction photovoltaic device of claim 14 wherein the n-type layer consists of polycrystalline silicon carbon (pc-SiC).

16. The tandem junction photovoltaic device of claim 14 wherein an effective composition of the p-type layer structure is approximately 35-45 at. % carbon and approximately 10-30 at. % germanium.

17. The tandem junction photovoltaic device of claim 14 wherein the layers of p-type polycrystalline silicon carbon in the p-type layer structure have a first thickness greater than a second thickness of the layers of p-type polycrystalline silicon germanium in the p-type layer structure.

18. The tandem junction photovoltaic device of claim 17 wherein the first thickness is approximately 20-30 nm and the second thickness is approximately 10-20 nm.

19. The tandem junction photovoltaic device of claim 14 wherein the plurality of alternating layers includes at least 40 layer pairs.

20. The tandem junction photovoltaic device of claim 14 further comprising:
a middle interconnect TCO layer disposed between the top cell and the bottom cell and in contiguous contact with the p-type layer structure of the top cell; and
an intrinsic zinc oxide layer disposed above the bottom cell and in contiguous contact with the middle interconnect TCO layer.
